(19) United States
(12) Patent Application Publication
(10) Pub. No.: US 2026/0262198 A1
(43) Pub. Date: Sep. 3, 2026

(54) Converter Cabinet, Computer Program Product and Converter with Improved Cooling

(71) Applicant: Siemens Aktiengesellschaft, Muenchen (DE)

(72) Inventors: Volker MÜLLER, Nuernberg (DE); Karl FLEISCH, Erlangen (DE)

(21) Appl. No.: 19/161,563

(22) PCT Filed: Jan. 19, 2024
(86) PCT No.: PCT/EP2024/051258

§ 371 Date: Sep. 2, 2025

(30) Foreign Application Priority Data
Mar. 3, 2023 (EP) 23159978.8

(51) Int. Cl. H05K 7/20; G06F 30/20

(52) U.S. Cl. CPC H05K 7/20409; G06F 30/20; H05K 7/20918; H05K 7/20927

(57) ABSTRACT

A converter cabinet includes walls within which a converter that includes a plurality of semiconductor switches and energy stores, a DC-link busbar system, a first heat sink for dissipating heat from the semiconductor switches, and a second heat sink for dissipating heat from the energy stores is arranged, wherein the first and the second heat sink are mechanically connected to one another, where the first and the second heat sinks are offset with respect to one another in a build direction of the converter, and computer program product include commands which, when executed by a computer, cause the computer to simulate an operating behavior of the converter in which a release of heat occurs.

### CROSS-REFERENCE TO RELATED APPLICATIONS

This is a U.S. national stage of application No. PCT/EP2024/051258 filed 19 Jan. 2024. Priority is claimed on European Application No. 23159978.8 filed 3 Mar. 2023, the content of which is incorporated herein by reference in its entirety.

### BACKGROUND OF THE INVENTION

### 1. Field of the Invention

The invention relates to a converter with improved cooling and a converter cabinet with such a converter, and relates to a computer program product for simulating the operating behavior of such a converter.

### 2. Description of the Related Art

Patent application CN 107733242 A discloses a water-cooled converter. The water cooling system of this converter is connected to a heat exchanger through which the waste heat of the converter is dissipated. The water cooling system comprises three sub-cooling systems which are each connected to an Insulated Gate Bipolar Transistor (IGBT) arm of the converter.

European patent application EP 0 677 916 A2 discloses a power converter system with air-cooled power semiconductors and a DC link circuit. The power semiconductors are arranged on the main surfaces of a cooling rail that is arranged adjacent to two partial capacitor batteries. A multiplicity of cooling channels is formed in the cooling rail.

Converters are used in a multiplicity of industrial applications and in energy supply technology, in which increasing demands are being placed on their electrical performance. This goes hand in hand with a need for more powerful cooling of the converters. At the same time, simple, cost-efficient production, robustness and reliability are required.

### SUMMARY OF THE INVENTION

It is an object of the invention to provide a converter which offers an improvement with respect to at least one of the above-described aspects.

This and other objects and advantages are achieved in accordance with the invention by a converter comprising a plurality of semiconductor switches and at least one energy storage device. The converter also has a DC-link busbar system via which at least one of the semiconductor switches is electrically connected to the at least one energy storage device. The at least one energy storage device may be formed as a capacitor. The converter also includes a first heat sink via which the semiconductor switches can be cooled. The semiconductor switches can be designed as Insulated Gate Bipolar Transistors (IGBTs), for example. For this purpose, the first heat sink is connected to the semiconductor switches in a thermally conductive manner. Furthermore, the converter in accordance with the invention has a second heat sink via which the energy storage devices can be cooled. For this purpose, the at least one energy storage device, which can be formed as a capacitor, for example, is connected to the second heat sink in a thermally conductive manner. During the operation of the converter, the semiconductor switches are essentially immediately cooled in the first heat sink and the energy storage devices are essentially immediately cooled in the second heat sink. The first and second heat sink are each liquid-cooled in configuration and mechanically connected to one another. In accordance with the invention, the first heat sink and the second heat sink are arranged offset from one another in a direction of assembly of the converter. The direction of assembly corresponds to the direction in which at least one semiconductor switch is mounted on the first heat sink and/or the at least one energy storage device is mounted on the second heat sink. As a result, the semiconductor switches and the at least one energy storage device can be cooled immediately by the first and second heat sinks, respectively. The mechanical connection between the first and second heat sinks is formed in the area of an offset in the direction of assembly. In accordance with the invention, ambient air in the vicinity of the converter can be cooled via the first and second heat sinks, which are arranged offset from one another. In this way, the heating of the ambient air, for example, in an associated converter cabinet, is counteracted.

In one embodiment of the converter, viewed in the direction of assembly, a detector is arranged in an area between the first and second heat sink. The detector can be arranged in the area of one side of the first heat sink that faces away from the semiconductor switches. The detector can be configured as a current measuring apparatus that can be electrically connected to the semiconductor switches. Furthermore, the detector can be connectable to a control unit of the converter. The inventive converter offers a space-saving option for mounting the detector.

In a further embodiment of the inventive converter, the first and second heat sinks are essentially flat in configuration at least in the area of the semiconductor switches or the energy storage devices. The heat sinks can therefore each essentially be described as disks in terms of their thermal conductivity. Furthermore, the essentially flat heat sinks are formed to be flat in an area of the at least one energy storage device or the semiconductor switches. This ensures large-scale thermal contact between the at least one energy storage device or semiconductor switches, and the respective heat sink. Moreover, flat heat sinks offer increased cooling performance. Moreover, the first and second heat sinks can be produced independently of one another. For example, the first heat sink can be made of a first material and the second heat sink can be made of a second material. Moreover, the first heat sink can be produced via a first production technology and the second heat sink can be produced via a second production technology. This results in an increased level of design freedom, allowing the heat sinks to be established to meet specific requirements.

Furthermore, the first and second heat sinks can be arranged essentially parallel to one another. This particularly means that at least one flat section, preferably the largest flat section, of each heat sink is arranged essentially parallel to the other. As a result, an essentially rectangular area can be defined, in which a hydraulic connection between the first and the second heat sink is formed. Furthermore, the parallel arrangement of the first and second heat sinks allows for simplified assembly of the converter.

In addition, cooling channels for throughflow with a cooling fluid may be formed in the first and/or second heat sinks. The cooling fluid is a liquid via which liquid cooling of the first and second heat sinks is provided. The first and second heat sinks can be forcibly cooled by the cooling fluid itself, in particular forcibly cooled from the inside. This ensures efficient heat dissipation from the first and/or second heat sinks. The heat sinks can be cooled via the cooling fluid in the heat sinks, in particular in a heat sink that is structurally separated from the converter, for example, outside a converter cabinet in which the converter is arranged. The cooling channels in the heat sinks can be hydraulically connected to one another or hydraulically separated. The first and second heat sinks can be cooled together via hydraulically connected cooling channels. As a result, thermal power losses on the at least one energy storage device or the semiconductor switches can be dissipated via the cooling fluid. Hydraulically connected cooling channels are also part of the thermally conductive connection between the heat sinks. Alternatively, hydraulically separated cooling channels allow the heat sinks to be cooled separately. Each of the heat sinks can thus be optimally configured for the waste heat to be expected on the at least one energy storage device and the semiconductor switches, respectively. This allows the configuration of the heat sinks to be needs-based, material and weight-saving.

In a further embodiment of the inventive converter, an intermediate space is formed between the first and second heat sinks through which air can flow to dissipate heat from the ambient air of the converter, for example, the ambient air in the interior space of a converter cabinet. In particular, the ambient air can be air that moistens the inventive converter directly. During normal operation, the ambient air may be heated by waste heat from the converter, which can lead to a harmful increase in the temperature of the ambient air in a converter cabinet. A thermal connection between the first and second heat sinks can be formed in the intermediate space so that air throughflow from the ambient air of the converter in the intermediate space is cooled in the first and/or second heat sinks. The intermediate space, which is at least partially delimited by the first and second heat sinks, can be formed as an air duct. The intermediate space is thus established to provide an enlarged surface area for cooling the ambient air of the converter. Thus, overall both efficient and compact cooling is provided for the converter and its ambient air. The thermal performance of the heat sinks can thus also be used for cooling of the ambient air. The converter can further be equipped with a fan, which may be mounted on the converter to allow air to flow into the intermediate space. The intermediate space, which is at least partially delimited by the heat sinks, is particularly suitable as an air duct through which air is blown by the fan. Fans are available in a wide range of sizes and performance classes, so that the fan can be easily adapted to the requirements of the inventive converter. The fan can be attached to a front side of the converter and can be selected essentially independently of structural restrictions arising from the electrical configuration of the converter. As a result, larger or more powerful fans can be used in the inventive converter than in the prior art. Furthermore, heat dissipation via a fan in the inventive converter can be easily calculated, and thus simulated in a simplified manner.

Furthermore, cooling fins may be formed in the intermediate space between the first and second heat sinks. The cooling fins may each be configured to connect to the first and/or second heat sink. In particular, the cooling fins may each be connected to only one of the heat sinks or to the first and second heat sink. The offset in the direction of assembly of the converter between the first and second heat sinks can be bridged by the cooling fins. The cooling fins can also serve as mechanical supports between the heat sinks. The cooling fins can be connected to the first and second heat sink in a thermally conductive manner and extend through the intermediate space through which air can flow. The cooling fins can be exposed to airflow from the fan. This increases the surface area exposed to air throughflow, thereby increasing the efficiency of heat dissipation from the ambient air around the converter. The increased surface area as a result of the cooling fins supports heat transfer from air throughflow into the first and/or second heat sinks. Accordingly, the cooling fins may be arranged in the air duct and essentially extend along the air duct. Furthermore, at least one of the cooling fins may have a cooling channel that forms a thermal connection to the first and/or second heat sink. This further increases the efficiency of overall heat dissipation from the converter. The cooling fins essentially allow rectangular cross-sections through which air flows to be defined in the air duct and they can be easily simulated.

In addition, the DC-link busbar system, which electrically connects at least one semiconductor switch to the at least one energy storage device, is configured to be stepless. Accordingly, the DC-link busbar system can be formed to be essentially flat, i.e., free of steps, such as by bending. Corresponding to the DC-link busbar system, at least one energy storage device and the associated semiconductor switch can be configured to be flush in the direction of assembly. For example, the DC-link busbar system can be formed as a stamped part that is free of bending. This simplifies the production of the inventive converter. The DC-link busbar system also has reduced inductance.

Furthermore, the converter may have a conductor rail that can be fastened to a side of the first heat sink facing away from the semiconductor switches. Alternatively or in addition, the conductor rail may be fastened to a side of the second heat sink facing away from the at least one energy storage device. The conductor rail may be electrically insulated from the first or second heat sink, for example, via a suitable intermediate layer or coating. The conductor rail is configured and arranged to use the first or second heat sink as a heat sink and thus to dissipate heat from the converter. The conductor rail may be electrically connected to at least one semiconductor switch. Furthermore, the conductor rail may be formed as an unbent stamped part and can thus be produced cost-effectively. In particular, the conductor rail can be designed to be flat and unbent, i.e., free of bending. The same applies to an insulating intermediate layer that can be arranged on a conductor rail. The insulating intermediate layers can thus also be attached to the conductor rail in a flat manner, allowing for automated production. This also simplifies the production of the claimed converter.

In a further embodiment of the inventive converter, a half-bridge, to which the semiconductor switches belong, is free of snubber capacitors. The inventive converter, in particular its conductor rail, has reduced stray inductance, as a result of which there is no need for snubber capacitors. The inventive converter therefore has a reduced number of components and can thus be produced more quickly. Furthermore, the reduced number of components increases the reliability of the inventive converter.

Furthermore, the second heat sink in the inventive converter may protrude beyond the at least one energy storage device on one side in a layer direction. The layer direction is understood to be a direction along the essentially flat second or first heat sink. The layer direction is essentially perpendicular to the direction of assembly of the converter. The second heat sink thus protrudes beyond the at least one energy storage device and forms a section that overlaps a section of the first heat sink in the direction of assembly. The corresponding sections of the first and second heat sinks can thus partially delimit the intermediate space between the heat sinks. Likewise, the corresponding sections can be part of the air duct, through which air can flow from the fan and/or in which cooling fins can be provided. By appropriately dimensioning the first and/or second heat sink, it is thus possible to specify a cross-section of the intermediate space or the associated air duct. The second heat sink can protrude at least partially beyond the at least one energy storage device in the layer direction to such an extent that it faces the first heat sink. Consequently, the intermediate space or the cooling channel in the layer direction may have a width which corresponds to the maximum dimension of the first heat sink in the layer direction. As a result, the inventive converter is easily scalable as regards cooling capacity. This allows the converter to be operated at increased electrical power, as a result of which correspondingly increased cooling capacity is required. At the same time, the inventive converter can be structured to save space. The second heat sink thus protrudes above the at least one energy storage device in the layer direction to increase the electrical power consumption capacity of the converter.

In addition, the first and/or second heat sink can be produced via additive manufacturing, for example, via laser sintering, 3D printing, or binder jetting. As a result, cooling channels in the heat sinks and/or cooling fins can be easily adapted to the inventive converter. In particular, the cooling channels can be adapted to the requirements of the converter, as a result of which increased cooling performance can be achieved for the converter.

The objects and advantages are also achieved in accordance with the invention by a converter cabinet comprising walls in which at least one converter is arranged. In accordance with the invention, the converter is configured in accordance with the disclosed embodiments outlined above. The converter can be arranged essentially vertically, with the fan arranged at a bottom end. Accordingly, the converter cabinet can be cooled by expelling the air throughflow from the cover side. Due to the increased cooling capacity of the inventive converter, the converter cabinet is suitable for accommodating a greater number of converters compared to conventional converter cabinets. Alternatively or in addition, the inventive converter cabinet is suitable for accommodating increased electrical power compared to conventional converter cabinets. The features of the converter in accordance with the disclosed embodiments are accordingly transferable to the inventive converter cabinet in an analogous manner.

The objects and advantages are also achieved in accordance with the invention by a method for simulating the operating behavior of a converter. The method comprises a first step in which a data set is provided, which can be used to simulate the operation of at least part of the converter to be simulated. In particular, the data set may comprise a digital image of the converter, i.e., represent its structure. This may include the size, position, shape, material specification and/or associated material properties of heat sinks, of at least one energy storage device, at least one semiconductor switch and/or one fan. Alternatively or in addition, the data set may include information about heat dissipation behavior, thermal conductivity and/or heat dissipation behavior.

The method according to the invention also comprises the specification of at least one operating condition that characterizes the operating behavior to be simulated. The operating condition may comprise an electrical load on the converter and/or an associated release of heat at the at least one semiconductor switch and/or at the at least one energy storage device. Alternatively or in addition, an ambient temperature and/or information about air inflow around the converter may be included in the operating conditions. The inventive method also includes a third step in which a computer program product is executed to process the data set provided in the first step in combination with the at least one operating condition specified in the second step. The computer program product is configured to simulate the operating behavior of the converter based on the data set and the at least one operating condition. In doing so, at least one operating parameter is determined. The operating parameter can be, for example, a temperature distribution on a surface and/or in the material of at least one heat sink, at least one energy storage device and/or at least one semiconductor element. Alternatively or in addition, the operating parameter may also comprise thermal information about the liquid with which at least one of the heat sinks is cooled. The computer program product may be formed from a “digital twin”, as described in more detail in U.S. Pub. No. 2017/286572A1 , for example, the content of which is incorporated herein by reference in its entirety.

A fourth step is also part of the method in accordance with the invention, in which the at least one operating parameter determined in the third step is output to a user and/or a data interface. The data interface is suitable for outputting the results of the method described above to other simulation-oriented computer programs. In accordance with the invention, the optical filter arrangement which is simulated by the method is configured in accordance with one of the above-described embodiments. The features of the converter in accordance with are accordingly transferable to the inventive method.

The objects and advantages are also achieved in accordance with the invention by a computer program product comprising commands which, when executed by a computer, cause the computer program product to simulate an operating method of a converter. In accordance with the invention, the computer program product is configured to perform the method in accordance with the above-described embodiments. Alternatively, the converter simulated by the computer program product may be configured in accordance with the above-described embodiments. Alternatively or in addition, the computer program product may be configured to correspondingly simulate the operating behavior of a converter cabinet in accordance with the above-described embodiments.

The operating method may include electrical behavior of the converter and/or its thermal behavior. The thermal behavior may include a release of heat at a semiconductor switch, an energy storage device, heat transfer to a DC-link busbar system, a conductor rail, a heat sink, or thermal conductivity in one of these components. Likewise, the thermal conductivity behavior may include heat transfer to a cooling fluid, a cooling fin and/or air throughflow passing over one of these components. The operating behavior can be determined as a function of at least one operating parameter, such as the electrical power consumption of the converter and/or the ambient air temperature. Furthermore, a fan speed or fan throughput can be a predeterminable operating parameter. The operating parameters can be provided by a user and/or a suitable data interface, for example, from another simulation-oriented computer program. The computer program product may further comprise a physics module with which the operating behavior can be adjusted, i.e., simulated. Likewise, the computer program product may be configured to output simulation results to a user and/or a suitable data interface, such as to another simulation-oriented computer program. The inventive computer program product can be designed as a “digital twin”, as described, for example, in U.S. Pub. No. 2017/0286572A1, the content of which is incorporated herein by reference in its entirety.

The simulated converter can be simulated in an advantageous manner due to its configuration. The air duct, in particular with cooling fins, can define at least one essentially rectangular cross-section through which air flows. Such rectangular cross-sections can be simulated in a simplified manner and can, for example, be represented with sufficient accuracy by a characteristic line that shows the present cooling capacity as a function of at least one present operating parameter. Furthermore, such increased cooling capacity can be achieved by the inventive converter that interfering influences and/or feedback effects that occur in converters or converter cabinets in accordance with the prior art, for example, due to heating of the ambient air, are largely negligible. As a result, the simulation of an inventive converter or an inventive converter cabinet is simplified. The inventive computer program product delivers meaningful simulation results with reduced computing power. Furthermore, the inventive computer program product is thus essentially real-time capable. An inventive converter or converters can be monitored more accurately during operation as a result of the inventive computer program product. For example, measured values from sensors in the converter or converter cabinet, in particular temperature values, can be checked for plausibility, and a defective component identified thereby. The inventive computer program product can be monolithic in structure, i.e., executable on a single hardware platform. Alternatively, the inventive computer program product can be modular in structure, i.e., comprise subprograms that can be executed on separate hardware platforms, interact via a communicative data connection, and thereby provide the intended simulation.

One embodiment of the inventive computer program product has a data interface which is configured to connect the computer program product to at least one sensor, which is assigned to a corresponding physical converter. The physical converter can be monitored together with the inventive computer program product during normal operation of the latter. The data interface is configured to determine a degree of agreement between the simulated operating behavior and the actual operating behavior on the basis of measurement signals or measurement values which are provided by the at least one sensor. In particular, the operating parameter determined in the inventive method, and thus by the inventive computer program product, may correspond to a measurement signal or measured value recorded in the physical converter with the at least one sensor. Furthermore, the data interface can be configured as an Application Programming Interface (API).

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is explained in more detail hereinafter with regard to individual embodiments in figures. The figures should be read in conjunction with each other in that the same reference characters in different figures have the same technical meaning. The features of the individual embodiments can also be combined with one another. Furthermore, the features of the embodiments shown in the figures can be combined with the features outlined above, in which:

FIG. 1 shows a side view of a first embodiment of the inventive;

FIG. 2 shows a section of a second embodiment of the inventive converter in a cutaway oblique view;

FIG. 3 shows an uncut oblique sectional view of the inventive convertor of FIG. 2;

FIG. 4 shows a third embodiment of the inventive converter in an oblique view from below;

FIG. 5 shows a third embodiment of the inventive converter in an oblique view from above;

FIG. 6 shows an embodiment of the inventive converter cabinet; and

FIG. 7 shows a flowchart of the inventive method.

### DETAILED DESCRIPTION OF THE EXEMPLARY EMBODIMENTS

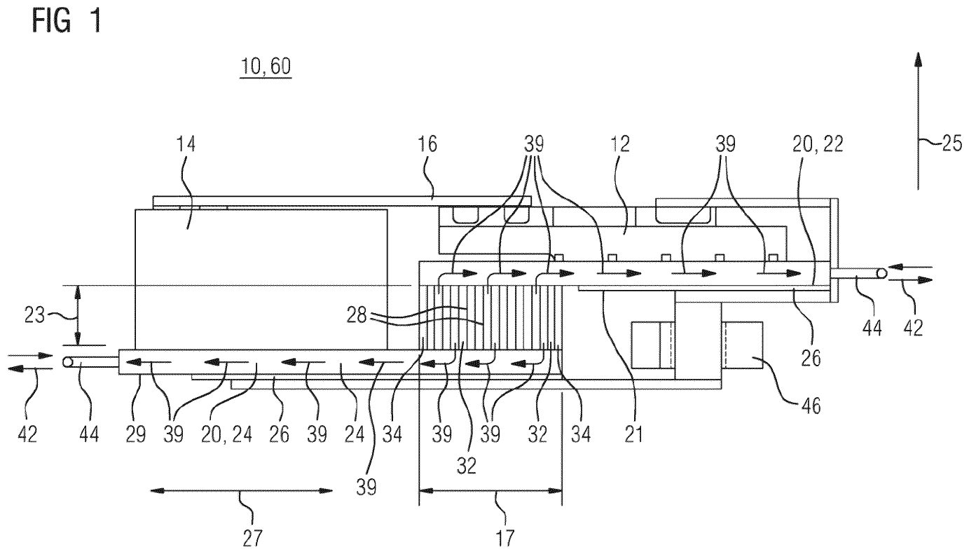

A first embodiment of the inventive converter 10 is shown diagrammatically in FIG. 1 in a side view. The converter 10 comprises an energy storage device 14 that is formed as a capacitor and is connected to the semiconductor switches 12. The energy storage device 14 is connected in an electrically conductive manner to a semiconductor switch 12 via a “DC-link” busbar system 16. The converter 10 likewise comprises heat sinks 20 via which heat is to be dissipated from the energy storage devices 14 and the semiconductor switches 12 during normal operation. During normal operation, the semiconductor switch 12 and the at least one energy storage device 14 generate heat flows 39 that are introduced into the heat sink 20. The semiconductor switches 12 are arranged on a first heat sink 22 and are in thermally conductive contact therewith. A cooling fluid line 44 is formed on the first heat sink 22, through which a cooling fluid 42 can be introduced into and/or discharged from the first heat sink 22. Heat absorbed by the cooling fluid 42 can thus be carried away from the converter 10, for example, to a structurally separate heat sink, which is not shown in detail in FIG. 1. Analogously, the at least one energy storage device 14 is arranged on a second heat sink 24 and is in thermally conductive contact therewith. Likewise, analogously to the first heat sink 22, the second heat sink 24 is provided with a cooling fluid line 44 into which a cooling fluid 42 can be introduced and/or from which it can be discharged. The first and second heat sinks 22, 24 are each essentially flat in structure. Accordingly, the first and second heat sinks 22, 24 extend essentially in a layer direction 27 and can essentially be described as disks in terms of their thermal behavior, i.e., their thermal conductivity. The first and second heat sinks 22, 24 are arranged parallel to one another and are arranged offset from one another in a direction of assembly 25 of the converter 10. The direction of assembly 25 is symbolized by the corresponding arrow in FIG. 1.

The second heat sink 24 is extended adjacent to the at least one energy storage device 14 and protrudes beyond it in the layer direction 27. The at least one energy storage device 14 protrudes beyond the second heat sink 24 by a protrusion width 17, in the region of which the second heat sink 24 faces the first heat sink 22. In the area of the protrusion width 17, there is an intermediate space 23 between the first and second heat sinks 22, 24. Supports 34 are arranged in the area of the intermediate space 23, via which the first heat sink 22 is supported on the second heat sink 24. Likewise, a thermally conductive connection is produced by the supports 34 between the first and second heat sinks 22, 24. Likewise, a plurality of cooling fins 28 is formed between the supports 34, and thus in the intermediate space 32, which is likewise connected in a thermally conductive manner to the first and second heat sinks 22, 24. Heat flows 39 generated during normal operation from the at least one energy storage device 14 and the semiconductor switches 12 can be introduced into the first and second heat sinks 22, 24 and dissipated via the cooling fluid 42. Likewise, heat flows 39 from the cooling fins 28 and the supports 34 are introduced into the first and second heat sinks 22, 24 and dissipated via the cooling fluid 42. Air can flow through the intermediate space 23 perpendicular to the drawing plane in FIG. 1 and the intermediate space thus forms an air duct 32. The cooling fins 28 are arranged such that the air duct 32, i.e., a cross-section through which air can flow lying between the supports 34, is segmented by the cooling fins 28. The cooling fins 28 provide an enlarged surface area that improves heat transfer from the air in the cross-section, through which air can flow, to the heat sinks 22, 24. The cooling fins 28 and/or the supports 34 can be produced via additive manufacturing. Furthermore, the intermediate space 23 in the direction of assembly 25 is structured such that at least one of the semiconductor switches 12 is flush with the at least one energy storage device 14 in the direction of assembly 25. Consequently, at least one of the DC-link busbar systems 16 that connects a semiconductor switch 12 to the at least one energy storage device 14 is formed to be stepless. The corresponding DC-link busbar system 16 is essentially flat in structure, in particular strip-shaped. The corresponding DC-link busbar system 16 is formed as a stamped part and can therefore be produced cost-effectively. Furthermore, electrically insulating intermediate layers 26 are attached to the first and the second heat sinks 22, 24 on a side 21, 29 facing away from the semiconductor switches 12 and the at least one energy storage device 14, respectively. The intermediate layers 26 electrically insulate a conductor rail 18 from the first and second heat sinks 22, 24, respectively.

A detector 46, which is configured as a current measuring apparatus, is arranged in an area between the first and second heat sink 22, 24 in the direction of assembly 25. The detector 46 is electrically connected to the semiconductor switch 12 and can be connected to a control unit of the converter 10, which is not shown in detail. The conductor rail 18 is formed as a bent stamped part and provides an electrical connection for the converter 10. The intermediate layer 26 is thermally permeable and establishes a thermally conductive connection from the first or second heat sinks 22, 24 to the conductor rail 18. The conductor rail 18 thus also supports the heat dissipation of the converter 10. Furthermore, there is a computer program product 60 via which the operating behavior of the converter 10 according to FIG. 1 is adjusted. The computer program product 60 is formed as a digital twin of the converter 10, here.

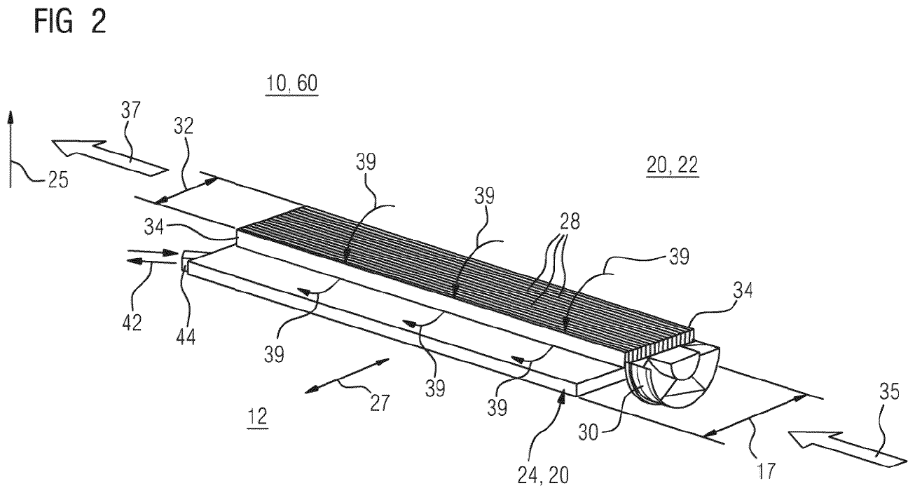

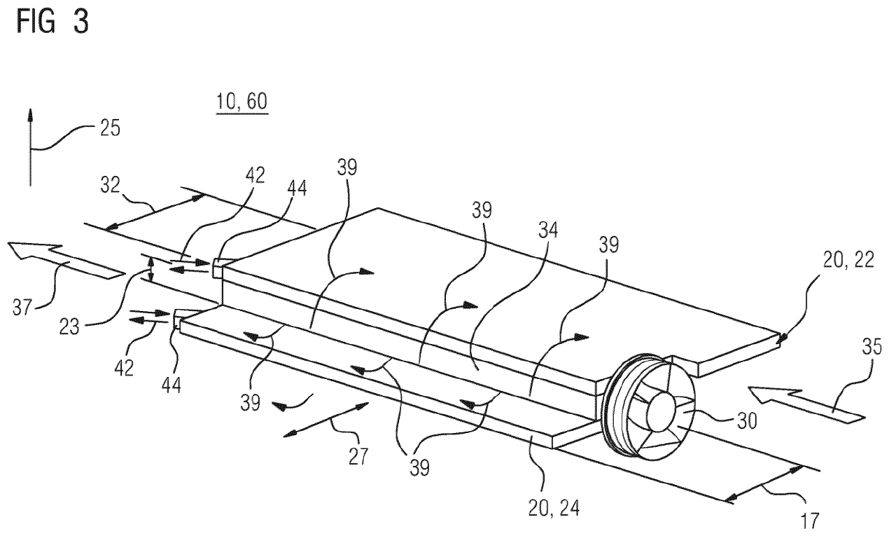

In FIG. 2 and FIG. 3, a second embodiment of the inventive converter 10 is shown diagrammatically in sectional view. FIG. 2 shows the structure in a cutaway oblique view and FIG. 3 shows the structure in an uncut oblique view. The converter 10 comprises a second heat sink 24 that protrudes beyond the at least one energy storage device 14, not shown in detail, in a layer direction 27 by a protrusion width 17. Supports 34 are formed in the area, which is defined by the protrusion width 17, between which cooling fins 28 are positioned. The cooling fins 28 extend parallel to one another and segment an air duct 32 between the supports 34. A fan 30 is arranged at one edge of the second heat sink 24, the diameter of which corresponds to at least the width of the cooling channel 32. The fan 30 can be used to force air inflow 35 through the converter 10 in a predetermined manner. The air of the air inflow 35 can be taken from the ambient air. The cooling channel 32 is therefore supplied with air by the fan 30. Heat flows 39 from the cooling fins 28 are introduced into the second heat sink 24 and a first heat sink 22 shown in more detail in FIG. 3. The heat introduced into the cooling fins 28 by the air inflow 35 is absorbed by the heat sinks 22, 24 and dissipated via the cooling fluid 42. The air outflow 37 is thus cooled relative to the air inflow 35 and can be introduced into the ambient air. The air mass that is supplied as air inflow 35 and is discharged as air outflow 37 represents an air throughflow in the air duct 32. Alternatively, the direction of flow of the air throughflow can also be reversed. The air duct 32 is closed off by the first heat sink 22, which is connected to the supports 34 and the cooling fins 28 in the direction of assembly 25. The first and second heat sinks 22, 24 are connected in a thermally conductive manner to the supports 34 and the cooling fins 28. The operating behavior of the converter 10, which includes the release of heat in the form of heat flows 39, is simulated by a computer program product 60 which is formed as a digital twin of the converter 10.

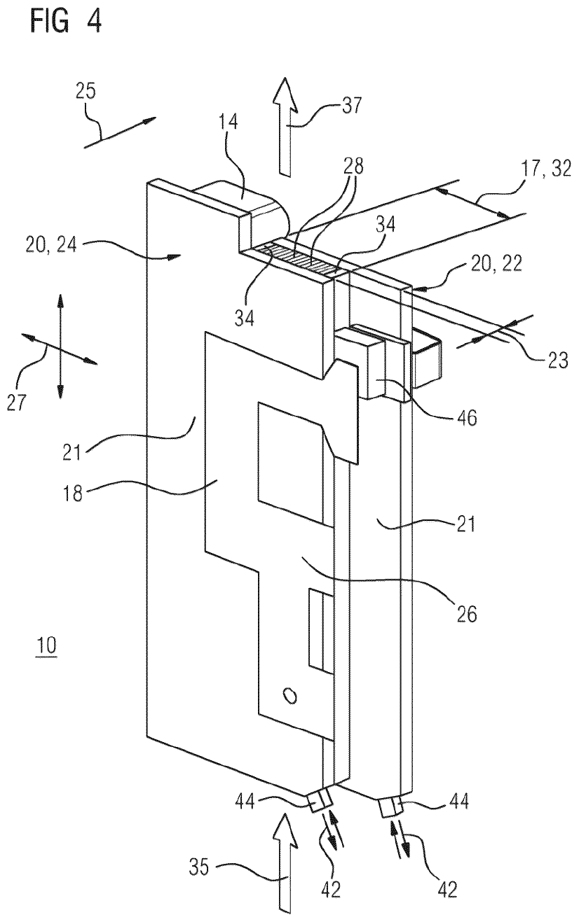

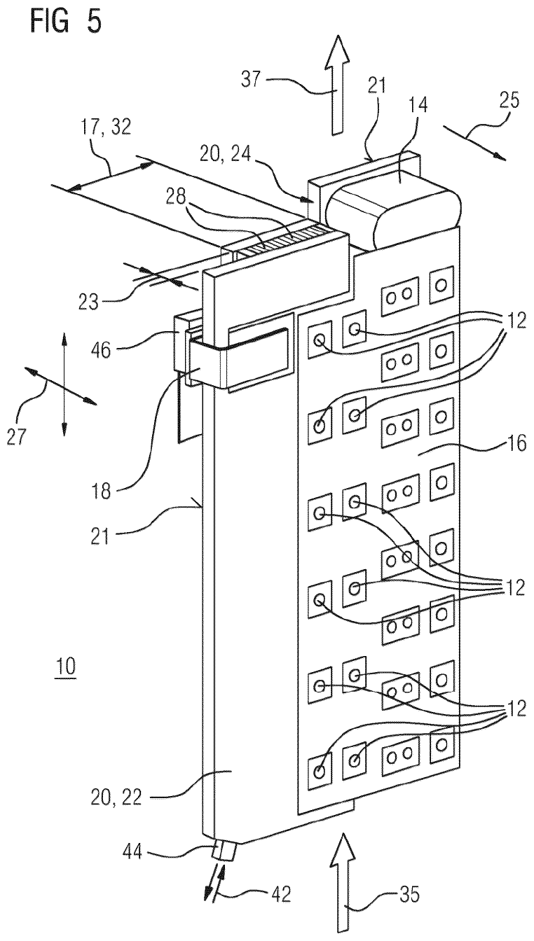

FIG. 4 and FIG. 5 further show a third embodiment of the inventive converter 10. The converter 10 is shown in an oblique view from opposite sides in FIG. 4 and FIG. 5. Relative to a direction of assembly 25, the converter 10 is shown from below in FIG. 4 and from above in FIG. 5. The converter 10 comprises heat sinks 20 on which semiconductor switches 12 and at least one energy storage device 14 are arranged. The at least one energy storage device 14, which is formed as a capacitor, is arranged on a first heat sink 22 and the semiconductor switches 12 are arranged on a second heat sink 24. In FIG. 5, the semiconductor switches 12 are partially covered by a DC-link busbar system 16 which is structured to be stepless and electrically connects at least one of the semiconductor switches to energy storage devices 14. The DC-link busbar system 16 is formed as a stamped part and is essentially flat. The first and second heat sinks 22, 24 are arranged at a distance from one another in the direction of assembly 25. Furthermore, the second heat sink 24 protrudes beyond the energy storage device 14 by a protrusion width 17 and, together with the first heat sink 22, partially delimits an intermediate space 23. An air duct 32 is formed in the area of the intermediate space 23 through which air can flow in a layer direction 27. The air duct 32 is segmented by a plurality of cooling fins 28, through which an air inflow 35 is directed through the converter 10. The cooling fins 28 are connected to the heat sinks 20 in a thermally conductive manner so that the air inflow 35 exits the converter 10 as a cooled air outflow 37. The converter 10 is also equipped with a conductor rail 18, which is mounted on a side 21 of the second heat sink 24 facing away from the semiconductor switches 12. The conductor rail 18 is formed of multiple parts and is electrically insulated from the second heat sink 24 by an intermediate layer 26. The intermediate layer 26 is thermally conductive in configuration and establishes a thermally conductive connection to the conductor rail 18. The cooling of the converter 10 is thus further supported by the conductor rail 18. The operating behavior of the converter 10 is simulated by a computer program product 60 which is designed as a digital twin of the converter 10.

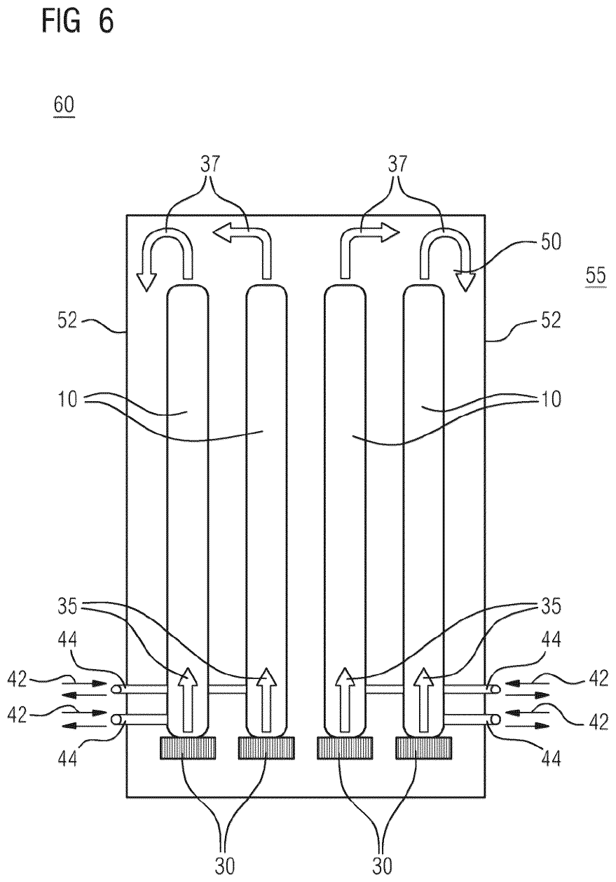

FIG. 6 shows a diagrammatic view of an embodiment of the inventive converter cabinet 50. The converter cabinet 50 comprises walls 52 that separate a plurality of converters 10 from an environment 55. The converters 10 are each equipped with a fan 30 through which air can flow onto the converters 10. The ambient air from the interior space of the converter 10 can be cooled by an air inflow 35 generated by the fans 30. The heat transported by the air inflow 35 is absorbed in the converter 10 and a cooled air outflow 37 is emitted into the interior space of the converter cabinet 50. The heat absorbed by the converter 10 is dissipated via cooling channels, not shown in detail, using a cooling fluid. At least one of the converters 10 is configured in accordance with one of the above-described embodiments and has increased cooling capacity. As a result, the converter cabinet 50 is suitable for accommodating a greater number of converters 10 compared to conventional converter cabinets, or for arranging them closer together. The converter cabinet 50 is hermetically sealed from the environment 55 so that air exchange with the environment 55 can be avoided. The entry of contaminants from the environment 55 is thus minimized. The operating behavior of at least one of the converters 10 in FIG. 6 is simulated by a computer program product 60. The computer program product 60 is formed as a digital twin of the corresponding converter 10.

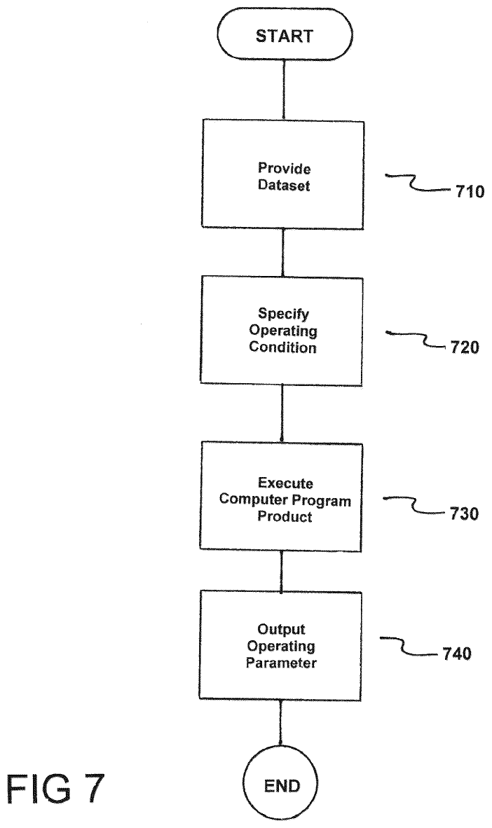

FIG. 7 is a flowchart of the method for simulating an operating behavior of a converter 10 comprising a plurality of semiconductor switches 12, at least one energy storage device 14, a DC-link busbar system 16, a first heat sink 22 for dissipating heat from the plurality of semiconductor switches 12, and a second heat sink 24 for dissipating heat from the at least one energy storage device 14.

The method comprises a) providing a dataset which is usable to simulate operation of at least part of the converter 10 to be simulated, as indicated in step 710.

Next, b) at least one operating condition that characterizes the operating behavior to be simulated is selected, as indicated in step 720.

Next, c) a computer program product 60 that is configured to simulate the operating behavior of the converter 10 based on the data set and the at least one operating condition and to determine at least one operating parameter is executed, as indicated in step 730.

Next, d) the at least one operating parameter is output to a user and/or a data interface, as indicated in step 740.

In accordance with the inventive method, wherein the first and/or second heat sinks 22, 24 are liquid-cooled, the first and second heat sinks 22, 24 are arranged offset from one another in a direction of assembly 25 of the converter 10 for dissipating heat from ambient air in an environment 55 of the converter 10. In addition, the direction of assembly corresponds to the direction in which at least one semiconductor switch 12 is mounted on the first heat sink 22 and/or the at least one energy storage device 14 is mounted on the second heat sink 24. Furthermore, the first heat sink 22 is connected to the second heat sink 24 via cooling fins 28.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-16. (canceled)

17. A converter, comprising:
a plurality of semiconductor switches;
at least one energy storage device;
a DC-link busbar system;
a first heat sink for dissipating heat from the plurality of semiconductor switches; and
a second heat sink for dissipating heat from the at least one energy storage device;
wherein at least one of the first and second heat sinks are liquid-cooled;
wherein the first and second heat sinks are arranged offset from one another in a direction of assembly of the converter for dissipating heat from ambient air in an environment of the converter;
wherein at least one of (i) the direction of assembly corresponds to the direction in which at least one semiconductor switch is mounted on the first heat sink and (ii) the at least one energy storage device is mounted on the second heat sink; and
wherein the first heat sink is connected to the second heat sink via cooling fins.

18. The converter as claimed in claim 17, wherein the first and second heat sinks have a flat configuration at least in an area of one of (i) the semiconductor switch and (ii) the at least one energy storage device.

19. The converter as claimed in claim 17, wherein the first and second heat sinks are arranged parallel to one another.

20. The converter as claimed in claim 17, wherein the first and second heat sinks are thermally connected to one other directly or indirectly.

21. The converter as claimed in claim 17, wherein the cooling channels are hydraulically connected to one another or are hydraulically separated.

22. The converter as claimed in claim 17, wherein an intermediate space is formed between the first and second heat sinks through which air flows to dissipate heat from the ambient air in an interior space of a converter cabinet.

23. The converter as claimed in claim 22, further comprising
a fan which is arranged to blow air into the intermediate space.

24. The converter as claimed in claim 17, wherein the DC-link busbar system comprises a stepless system.

25. The converter as claimed in claim 17, further comprising:
a conductor rail which is attached to at least one of (i) a side of the first heat sink facing away from the plurality of semiconductor switches and (ii) a side of the second heat sink facing away from the at least one energy storage device.

26. The converter as claimed in claim 17, wherein a half-bridge to which the plurality of semiconductor switches belong is configured without snubber capacitors.

27. The converter as claimed in claim 17, wherein the second heat sink protrudes beyond the at least one energy storage device on one side in a layer direction.

28. The converter is claimed in claim 17, wherein at least one of the first and second heat sink is produced via additive manufacturing.

29. A converter cabinet, comprising walls within which at least one converter is arranged, wherein the converter is configured designed as claimed in claim 17.

30. A method for simulating an operating behavior of a converter comprising a plurality of semiconductor switches, at least one energy storage device, a DC-link busbar system, a first heat sink for dissipating heat from the plurality of semiconductor switches, and a second heat sink for dissipating heat from the at least one energy storage device, the method comprising:
a) providing a dataset which is usable to simulate operation of at least part of the converter to be simulated;
b) specifying at least one operating condition which characterizes the operating behavior to be simulated;
c) executing a computer program product which is configured to simulate the operating behavior of the converter based on the data set and the at least one operating condition and to determine at least one operating parameter; and
d) outputting the at least one operating parameter to at least one of a user and a data interface;
wherein the at least one of the first and second heat sinks are liquid-cooled;
wherein the first and second heat sinks are arranged offset from one another in a direction of assembly of the converter for dissipating heat from ambient air in an environment of the converter;
wherein at least one of (i) the direction of assembly corresponds to the direction in which at least one semiconductor switch is mounted on the first heat sink and (ii) the at least one energy storage device is mounted on the second heat sink; and
wherein the first heat sink is connected to the second heat sink via cooling fins.

31. A computer program product comprising commands which, when executed by a computer, cause the computer to simulate the operating behavior of a converter in which a release of heat occurs, wherein the computer program product is configured to perform the method as claimed in claim 30.

32. The computer program product as claimed in claim 15, wherein the computer program product comprises a data interface which is configured to connect the computer program product to a sensor which is assigned to a corresponding physical converter.
